(19) United States
(12) Patent Application Publication
(10) Pub. No.: US 2024/0043614 A1
(43) Pub. Date: Feb. 8, 2024

(54) FLUORORESIN

(71) Applicant: CHEMOURS-MITSUI FLUOROPRODUCTS CO., LTD, TOKYO (JP)

(72) Inventors: GEN EGASHIRA, SHIZUOKA (JP); MASAKI MUGISAWA, SHIZUOKA (JP); KAZUYA ICHINOSE, SHIZUOKA (JP); KEIGO HIGASHIDA, SHIZUOKA (JP)

(73) Assignee: CHEMOURS-MITSUI FLUOROPRODUCTS CO., LTD., TOKYO (JP)

(21) Appl. No.: 18/039,847

(22) PCT Filed: Dec. 3, 2021
(86) PCT No.: PCT/US2021/061691

§ 371 Date: Jun. 1, 2023

(30) Foreign Application Priority Data
Dec. 3, 2020 (JP) 2020-201154
Sep. 17, 2021 (JP) 2021-152043

(51) Int. Cl. C08G 65/40; C08J 5/24; H05K 1/03

(52) U.S. Cl. CPC C08G 65/4006; C08J 5/24; H05K 1/0366; C08J 2365/00; C08G 2650/48; H05K 2201/015

(57) ABSTRACT

Provided is a novel fluororesin useful as an electronic substrate material for high speed transmission. The fluorine resin has the structure of Formula (I), wherein n is within a range of 1 to 100, L has the structure in Formula (II) or Formula (III), R¹ and R² are independently hydrogen atoms, C₁ to C₁₀ alkyl groups, C₁ to C₁₀ haloalkyl groups, or C₆ to C₁₀ aryl groups, or R¹ and R² may be combined to form a ring structure that may include a substituent, R³ and R⁴ are each independently hydrogen, fluorine, C₁ to C₁₀ saturated or unsaturated hydrocarbon groups in which a portion of or all hydrogens may be substituted with a halogen, and C₆ to C₁₀ aryl groups in which a portion of or all hydrogens may be substituted with a halogen, and X is a group containing an olefinic carbon-carbon double bond or a carbon-carbon triple bond and at least one fluorine atom.

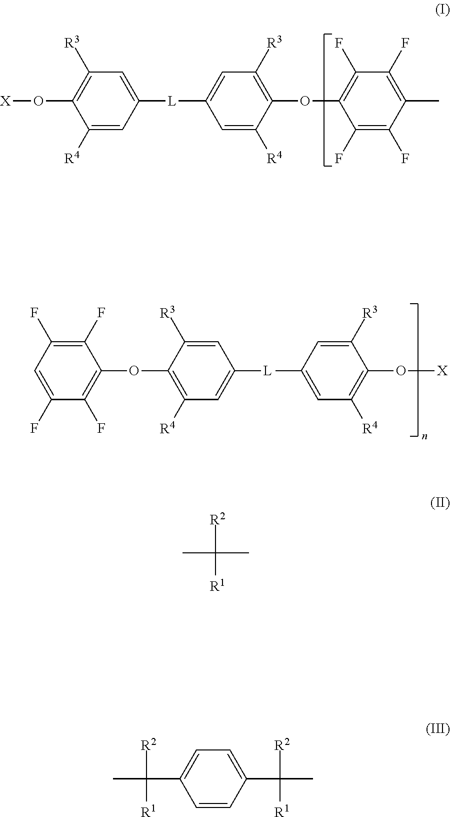

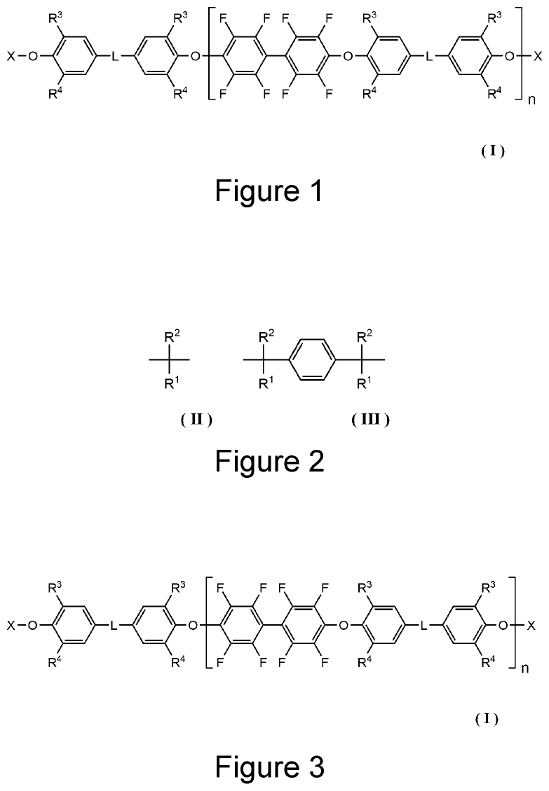

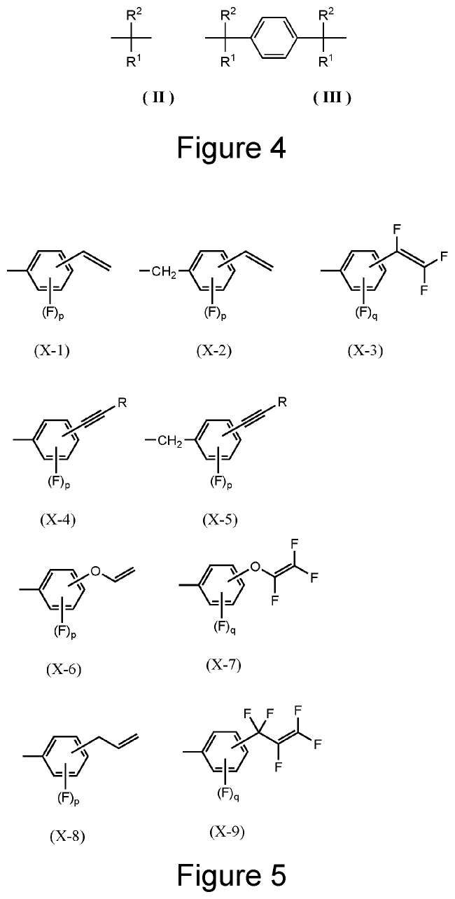

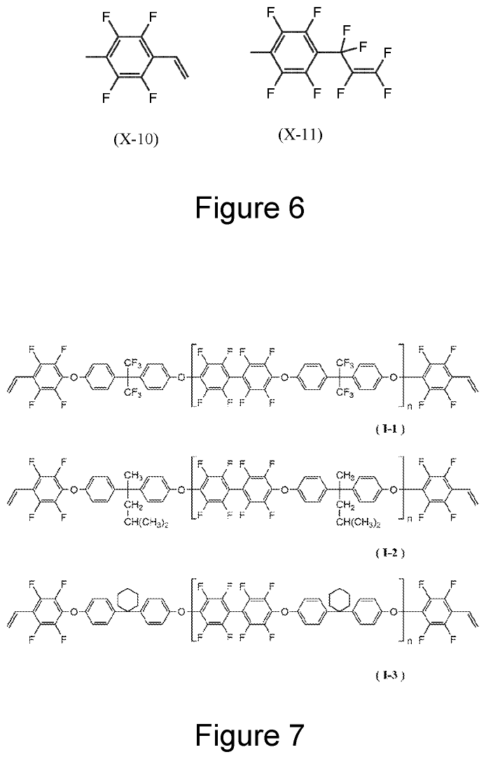

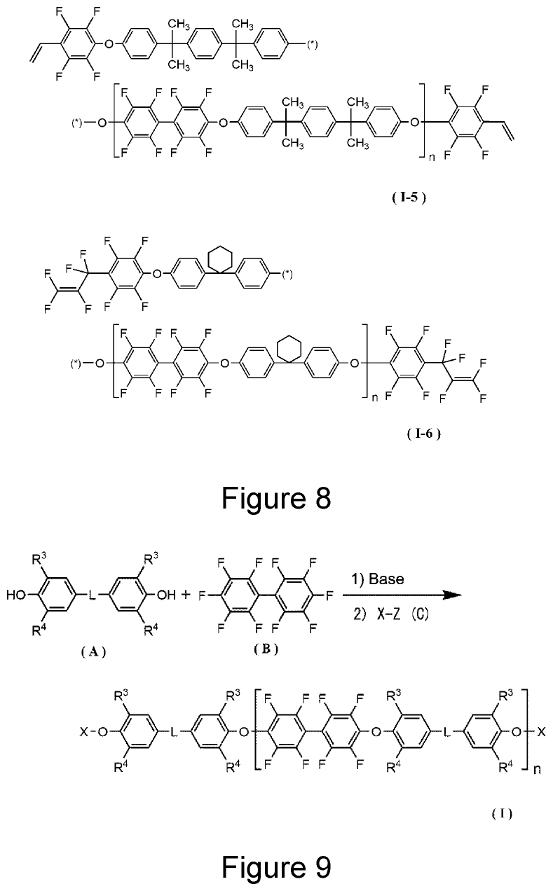

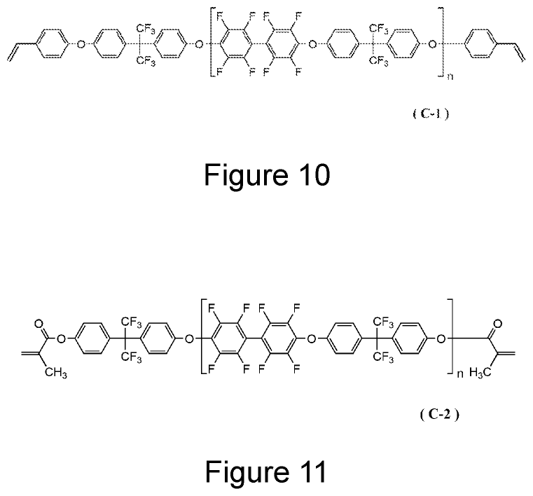

### CROSS REFERENCE TO RELATED APPLICATIONS

This application claims priority to Japanese Patent Application No. JP2020-201154 filed Dec. 3, 2020 and Japanese Patent Application No. JP2021-152043 filed Sep. 17, 2021, the disclosures of which are incorporated herein by reference in their entirety.

### TECHNICAL FIELD

The present invention relates to a novel fluororesin. More specifically, the present invention relates to a novel fluororesin that is useful as an electronic substrate material for high speed transmission.

### BACKGROUND TECHNOLOGY

Recently, there has been an increased demand for high speed communication and high speed transmission. High frequency signals must be conveyed without attenuation thereof for high speed transmission. Therefore, there is a demand for a material having a low dielectric constant and low dielectric loss in wire covering materials and substrate materials for signal transmission.

Conventionally, materials such as epoxy resins and polyphenylene ether resins have been used as resin materials for high speed communication and transmission (see Patent Document 1). However, the electrical characteristics (dielectric constant, dielectric loss, etc.) of conventionally known epoxy resins and polyphenylene ether resins are insufficient for the recent demand for high speed communication and transmission.

In contrast, fluororesins are known as materials having excellent electrical characteristics. In particular, perfluororesins in which all of the hydrogen in the molecular chain is substituted with fluorine are known to exhibit particularly excellent electrical characteristics (dielectric constant, dielectric loss, etc). Unfortunately, fluororesins (perfluororesins) have issues such as ease of deformation (due to stress) and a high thermal expansion coefficient, making them difficult to use as substrate materials. To solve the abovementioned problems, attempts have been made to mix fillers with a fluororesin. However, the mixing of fillers is known to negatively affect the electrical characteristics.

It has been proposed to use fluorinated poly (arylene ether) and crosslinkable fluorinated poly(arylene ether) as the dielectric material in electronic components (see Patent Documents 2 and 3). Unfortunately, the electrical characteristics of the materials do not satisfy the current high speed communication and transmission requirements.

Moreover, in terms of mass production as well as reducing manufacturing costs, the crosslinking treatment temperature must be reduced.

### PRIOR ART DOCUMENTS

[Patent Document 1] Japanese Unexamined Patent Application Publication No. 2017-128718
[Patent Document 2] U.S. Pat. No. 5,115,082 A
[Patent Document 3] U.S. Pat. No. 5,179,188 A

### SUMMARY OF THE INVENTION

As substrate materials for high speed communication and transmission, there is a demand for a resin material having excellent electrical characteristics (low dielectric constant and low dielectric loss), excellent dimensional stability (low thermal expansion coefficient), high solvent solubility for ease of thin film molding, and excellent crosslinking characteristics which allow films to be formed by heating at approximately 200° C.

Embodiment 1 of the present invention relates to a fluororesin having the structure of Formula (I):

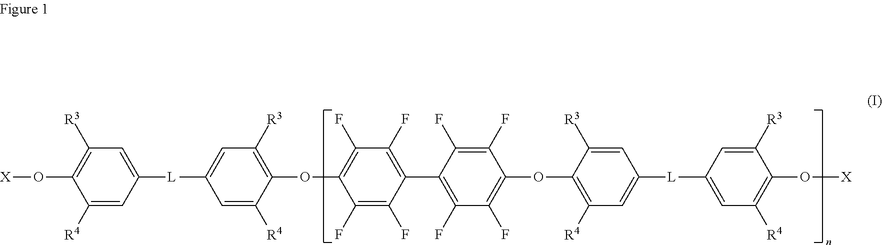

In the formula, L has the structure of formula (II) or formula (III),

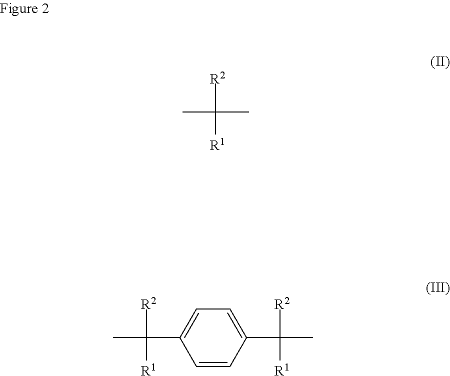

R¹ and R² are each independently a group selected from a group consisting of a hydrogen atom, C₁-C₁₀ alkyl groups, C₁-C₁₀ haloalkyl groups, and C₆-C₁₀ aryl groups, or R¹ and R² may be combined to form a ring structure that may include substituent, R³ and R⁴ are each independently a group selected from a group consisting of hydrogen atoms, fluorine atoms, C₁-C₁₀ saturated or unsaturated hydrocarbon groups in which some or all of the hydrogen atoms may be substituted by a halogen, and C₆-C₁₀ aryl groups in which some or all of the hydrogen atoms may be substituted by a halogen, n is in the range of 1 to 100, and X is a group containing an olefinic carbon-carbon double bond or a carbon-carbon triple bond and at least one fluorine atom.

Embodiment 2 of the present invention relates to a resin composition, including the fluororesin of Embodiment 1 and a crosslinking agent.

Embodiment 3 of the present invention relates to a prepreg, including a semicured product of the fluororesin according to Embodiment 1 and a fibrous base material.

Embodiment 4 of the present invention relates to a prepreg, including a semicured product of the resin composition according to Embodiment 2 and a fibrous base material.

Embodiment 5 of the present invention relates to a copper clad laminate, including a cured product of the prepreg according to Embodiment 3 or 4 and at least one copper layer.

Embodiment 6 of the present invention relates to a printed circuit board, including a cured product of the prepreg according to Embodiment 3 or 4 and a conductor pattern formed on the surface of the cured product.

### EFFECT OF THE INVENTION

By employing the abovementioned configuration, the present invention can provide a fluororesin having excellent electrical characteristics (low dielectric constant and low dielectric loss), excellent dimensional stability, high solvent solubility, and excellent crosslinking characteristics. The fluororesin of the present invention can be suitably used as a material of construction of a substrate for high speed communication and transmission.

### DESCRIPTION OF THE PREFERRED EMBODIMENTS

The fluororesin according to Embodiment 1 of the present invention has the structure of Formula (I):

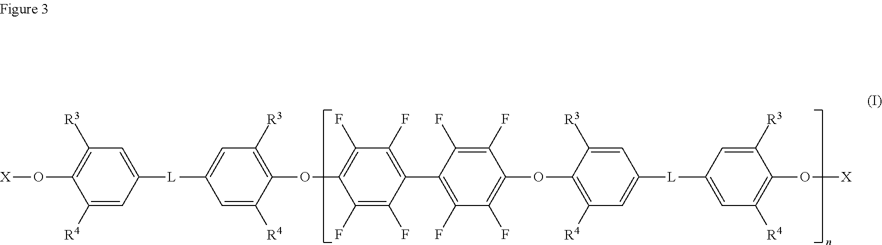

In the formula, L has the structure of formula (II) or formula (III),

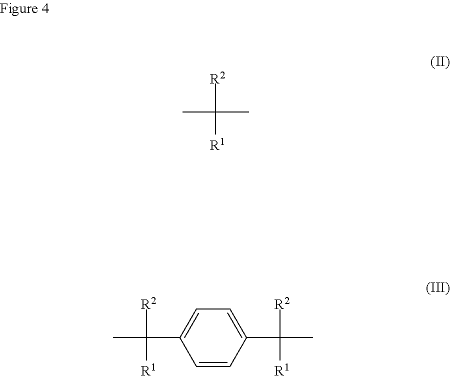

R¹ and R² are each independently a group selected from a group consisting of a hydrogen atom, C₁-C₁₀ alkyl groups, C₁-C₁₀ haloalkyl groups, and C₆-C₁₀ aryl groups, or R¹ and R² may be combined to form a ring structure that may include a substituent, R³ and R⁴ are each independently a group selected from a group consisting of hydrogen atoms, fluorine atoms, C₁-C₁₀ saturated or unsaturated hydrocarbon groups in which some or all of the hydrogen atoms may be substituted by a halogen, and C₆-C₁₀ aryl groups in which some or all of the hydrogen atoms may be substituted by a halogen, n is in the range of 1 to 100, and X is a group containing an olefinic carbon-carbon double bond or a carbon-carbon triple bond and at least one fluorine atom.

In Formula (I), n is within a range of 1 to 100, preferably within a range of 3 to 50, and more preferably within a range of 5 to 30. By setting n within the abovementioned range, sufficient heat resistance, an appropriate glass transition temperature (Tg), and sufficient solvent solubility can be simultaneously achieved. Moreover, by setting n within the abovementioned range, the number of substituents X included in the resin with a unit weight can be adjusted to achieve the appropriate crosslinking characteristics and excellent electrical characteristics (dielectric constant, dielectric loss, etc). Moreover, when forming a varnish using a fluororesin having the structure of Formula (I), n can be within the abovementioned range in order to impart the appropriate viscosity to the varnish.

In Formula (II) and Formula (III), R¹ and R² may independently be groups selected from the group consisting of hydrogen atoms, C₁ to C₁₀ alkyl groups, C₁ to C₁₀ haloalkyl groups, and C₆ to C₁₀ aryl groups. Exemplary C₁ to C₁₀ alkyl groups include methyl groups, ethyl groups, propyl groups, 2-methylpropyl groups (isobutyl groups), butyl groups, pentyl groups, etc. Exemplary C₁ to C₁₀ haloalkyl groups include trifluoromethyl groups, pentafluoroethyl groups, perfluoropropyl groups, etc. Exemplary C₆ to C₁₀ aryl groups of include phenyl groups and naphthyl groups (including 1-isomers and 2-isomers).

Alternatively, R¹ and R² may be taken together to form a ring structure which may have a substituent. Exemplary groups forming a ring structure include tetramethylene groups (forming a cyclopentane ring), pentamethylene groups (forming a cyclohexane ring), undecamethylene groups (forming a cyclododecane ring), 2-methyl-pentamethylene groups (forming a methylcyclohexane ring), 2,2,4-trimethyl-pentamethylene group (forming a trimethylcyclohexane ring), biphenyl -2,2′-diyl groups (forming a fluorene ring), etc.

In Formula (I), R³ to R⁴ may each independently be hydrogen, fluorine, C₁ to C₁₀ saturated or unsaturated hydrocarbon groups in which a portion of or all hydrogens may be substituted with a halogen, or C₆ to C₁₀ aryl groups in which a portion of or all hydrogens may be substituted with a halogen. Exemplary C₁ to C₁₀ saturated or unsaturated hydrocarbon groups in which a portion of or all hydrogens may be substituted with a halogen include methyl groups, ethyl groups, propyl groups, 2-methylpropyl groups (isobutyl groups), butyl groups, pentyl groups, trifluoromethyll groups, pentafluoroethyl groups, perfluoropropyl groups, vinyl groups, allyl groups, 1-methylvinyl groups, 2-butenyl groups, 3-butenyl groups, etc. Exemplary C₆ to C₁₀ aryl groups in which a portion of or all hydrogens may be substituted with a halogen include phenyl groups, naphthyl groups (including 1-isomers and 2-isomers), perfluorophenyl groups, etc.

In Formula (I), X is a group containing an olefinic carbon-carbon double bond or a carbon-carbon triple bond and at least one fluorine atom. Examples of X include the following structures (X-1) through (X-9).

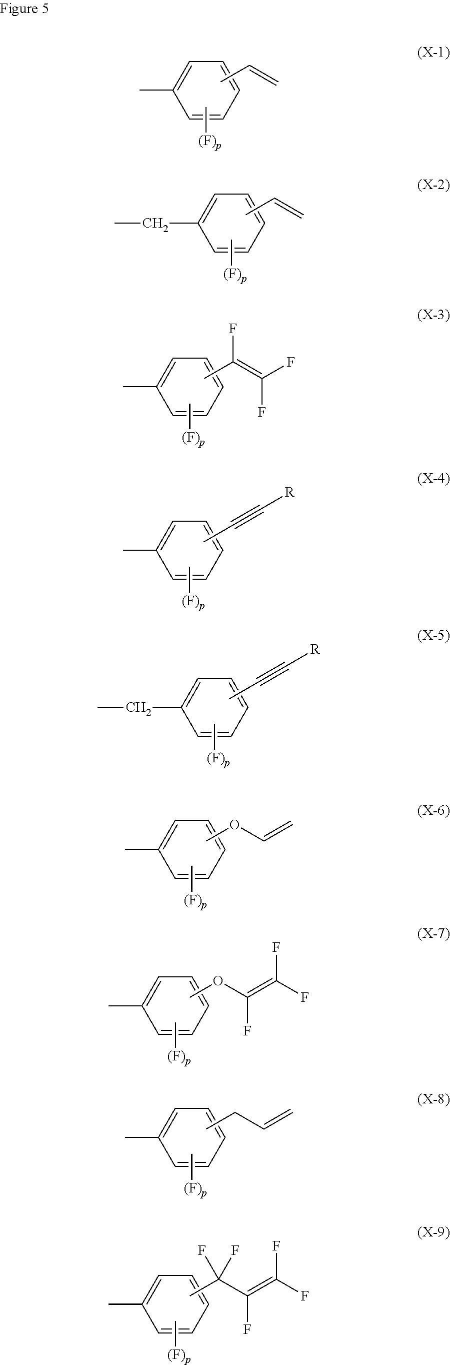

In the formula, p is an integer of 1 to 4, preferably 4. Q is an integer of 0 to 4, preferably 4. R represents a group selected from the group consisting of C₁ to C₁₀ alkyl groups and C₆ to C₁₀ aryl groups.

Preferably, X has the following structure (X-10) or (X-11).

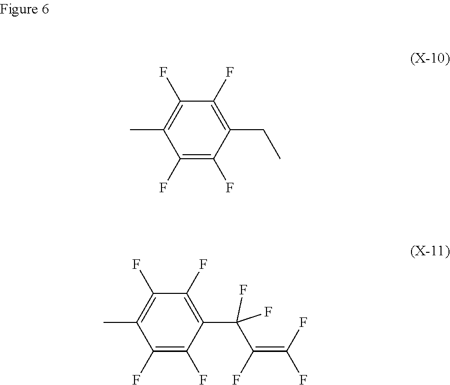

Preferable examples of fluororesins in the present invention include resins having the following structure (in the formula, “(*)” indicates a bonding position).

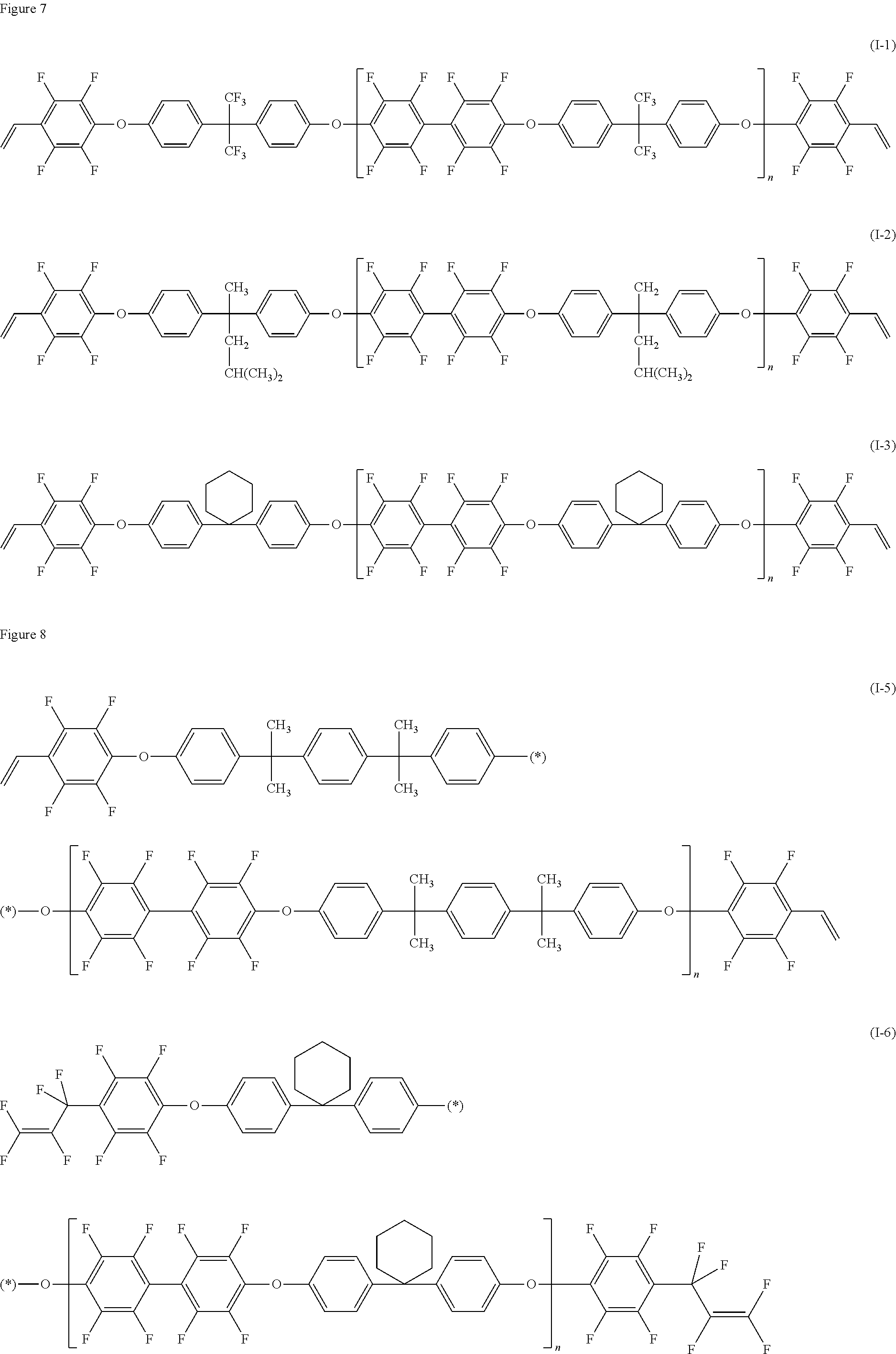

In the present invention, the fluororesin is preferably solvent soluble. The fact that the fluororesin is “solvent soluble” means that 1 g or more, preferably 10 g or more, of the fluororesin can be dissolved per 100 g of the solution obtained from a given solvent. The fluororesin of the present embodiment is preferably soluble in the below-mentioned hydrocarbons. Moreover, in terms of cost, the fluororesin of the present embodiment is particularly preferably soluble in toluene.

The fluororesin of the present invention can be manufactured via a method including the steps of: (1) condensing a bisphenol derivative (A) with a perfluoro biphenyl (B) in the presence of a base; and (2) condensing a precursor (C) of the substituent X with the obtained condensate.

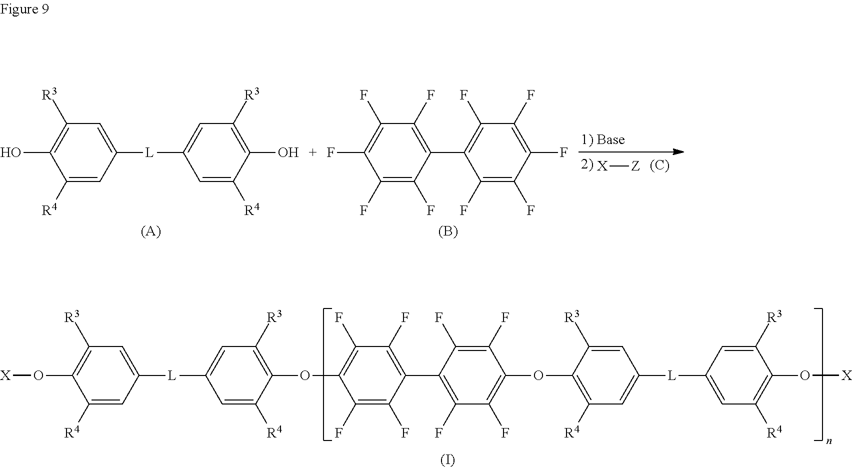

Z in the precursor (C) is a leaving group, preferably selected from the group consisting of F, Cl, Br, and I, and more preferably F.

The base to be used preferably includes an alkali metal carbonate, a hydrogen carbonate, and a hydroxide. Exemplary preferable bases include sodium carbonate, potassium carbonate, sodium hydrogen carbonate, potassium hydrogen carbonate, sodium hydroxide, and potassium hydroxide. One or more moles, preferably 2.0 to 2.6 moles, of base is preferably used per 1 mole of the bisphenol derivative (A).

Steps (1) and (2) are preferably carried out in an aprotic polar solvent or in a mixed solvent containing an aprotic polar solvent. Exemplary preferable aprotic polar solvents include N,N-dimethylformamide (DMF), N,N-dimethylacetamide (DMAc), dimethyl sulfoxide (DMSO), sulfolane, etc. The mixed solvent may include a low polarity solvent, so long as it neither reduces the solubility of the fluororesin nor affects the condensation reaction. Exemplary low polarity solvents capable of being used include toluene, xylene, benzene, tetrahydrofuran, benzotrifluoride ((trifluoromethyl)benzene), xylene hexafluoride (1,3-bis(trifluoromethyl)benzene), etc. The polarity (dielectric constant) of the solvent mixture can be changed by the addition of a low polarity solvent to control the speed of the condensation reaction.

Steps (1) and (2) are preferably carried out continuously. All of steps (1) and (2) are preferably carried out under conditions of a reaction temperature of 10 to 200° C. and a reaction time of 1 to 80 hours, preferably a reaction temperature of 20 to 180° C. and a reaction time of 2 to 60 hours, and more preferably a reaction time of 50 to 160° C. and a reaction time of 3 to 40 hours.

Embodiment 2 of the present invention relates to a resin composition, including the fluororesin of Embodiment 1 and a crosslinking agent.

The crosslinking agent used in the present embodiment includes a compound having two or more olefinic carbon-carbon double bonds in the molecule. Exemplary crosslinking agents used in the present embodiment include a polyfunctional methacrylate compound having two or more methacryl groups in the molecule, a polyfunctional acrylate compound having two or more acrylic groups in the molecule, a trialkenyl isocyanurate compound (such as triallyl isocyanurate (TAIC)), divinylbenzene, etc. Exemplary polyfunctional acrylate/methacrylate compounds include: dicyclopentadiene type acrylate compounds such as tricyclodecane dimethanol diacrylate; and dicyclopentadiene type methacrylate compounds such as tricyclodecane dimethanol dimethacrylate.

The resin composition of the present embodiment may contain up to 50 mass %, preferably up to 20 mass %, of the crosslinking agent, based on the total mass of the resin composition. Moreover, in the resin composition of the present embodiment, the mass ratio of the fluororesin to the crosslinking agent is preferably within a range of 9.5:0.5 to 5:5, more preferably within a range of 7.5:2.5 to 5.5:4.5. The use of the mass ratio within this range can impart sufficient hardness to the cured product of the resin composition.

The resin composition of the present embodiment may further contain a solvent, a reaction initiator, and/or a filler. Moreover, the resin composition of the present embodiment may further contain any additives known in the art, such as antifoaming agents, thermal stabilizers, antistatic agents, ultraviolet absorbers, colorants (dyes or pigments), flame retardants, lubricants, and dispersants.

The resin composition of the present embodiment may be a varnish-like composition containing a solvent. In the present embodiment, various solvents can be used. In terms of solvent solubility, an aprotic solvent is preferably used in the present invention. The solvent used in the present embodiment may include: hydrocarbons such as benzene, toluene, xylene, heptane, cyclohexane, methylcyclohexane, and mineral spirits; ketones such as acetone, methyl ethyl ketone (MEK), methyl isobutyl ketone (MIBK), and diisobutyl ketone (DIBK); cyclic ketones such as cyclohexanone, cycloheptanone, and cyclooctanone; esters such as ethyl acetate, butyl acetate, and γ-butyrolactone; cyclic ethers such as tetrahydrofuran (THF) and 1,3-dioxolane; amides such as N,N-dimethylformamide (DMF), diethylformamide (DEF), N,N-dimethylacetamide (DMAc), N-methylpyrrolidone (NMP) and N-cyclohexyl pyrrolidone; sulfones such as sulfolane and dimethylsulfone; and sulfoxides such as dimethylsulfoxide (DMSO). Preferable solvents for the present invention are hydrocarbons, particularly preferably aromatic hydrocarbons.

The resin composition of the present embodiment preferably includes a reaction initiator for a crosslinking reaction. Although crosslinking and curing by heating are possible in the absence of an initiator, if a reaction initiator is present, more efficient crosslinking and curing is possible under milder conditions. Exemplary reaction initiators capable of being used include benzoyl peroxide, di-t-butyl peroxide, t-butyl hydroperoxide, dicumyl peroxide, cumyl hydroperoxide, α, α′-di(t-butylperoxy)-diisopropylbenzene (Parbutyl P available from NOF Corporation), 2,5-dimethyl-2,5-di(t-butylperoxy)-3-hexyne, 3,3′,5,5′-tetramethyl-1,4-diphenaquinone, chloranyl, 2,4,6-tri-t-butylphenoxyl, t-butyl peroxyisopropyl monocarbonate, azobisisobutyronitrile, etc.

The resin composition of the present embodiment may further include one or more fillers. The filler may be an organic filler or an inorganic filler. Exemplary organic fillers capable of being used include: engineering plastics such as polyphenylene sulfide, polyetheretherketone (PEEK), polyamide, polyimide, and polyamide-imide; and solvent insoluble fluororesins such as polytetrafluoroethylene (PTFE), perfluoroalkoxy alkane (PFA), and copolymer of tetrafluoroethylene and hexafluoropropylene (FEP). Exemplary inorganic fillers capable of being used include: metals; metal oxides such as aluminum oxide, zinc oxide, tin oxide, and titanium oxide; metal hydroxides; titanic acid metal salts; zinc borate; zinc stannate; boehmite; silica; glass; silicon oxide; silicon carbide; boron nitride; calcium fluoride; carbon black; mica; talc; barium sulfate; molybdenum disulfide; etc. Solvent insoluble fluororesin is preferable in terms of improving the electrical characteristics (dielectric constant, dielectric loss, etc.) of the cured product of the resin composition. Moreover, silica is preferable in that the thermal expansion coefficient can be reduced without impairing the electrical characteristics (dielectric constant, dielectric loss, etc.) of the cured product of the resin composition.

The resin composition of the present embodiment can be formed by mixing the fluororesin of Embodiment 1, a crosslinking agent, and an optional component. Heating may be carried out during mixing. Mixing can also be carried out using any mixing apparatus known in the art, such as various stirrers, ball mills, bead mills, planetary mixers, and roll mills.

Embodiment 3 of the present invention relates to a prepreg, including a semicured product of the fluororesin according to Embodiment 1 and a fibrous base material. The prepreg of the present embodiment may further include a reaction initiator for a crosslinking reaction. The initiator capable of being used in the present embodiment is the same as that of Embodiment 2.

Exemplary fibrous base materials capable of being used in the present embodiment include glass woven fabrics, aramid woven fabrics, polyester woven fabrics, carbon fiber woven fabrics, glass nonwoven fabrics, aramid nonwoven fabrics, polyester nonwoven fabrics, carbon fiber nonwoven fabrics, pulp paper, linter paper, etc. A preferable fibrous substrate is a glass woven fabric capable of achieving excellent mechanical strength. The fibrous base material desirably has a thickness of 0.01 mm to 0.3 mm.

The prepreg of the present embodiment can be formed by impregnating the fluororesin according to Embodiment 1 and an optional initiator into the fibrous base material and drying them. Here, the fluororesin to be impregnated is preferably in a varnish state containing a solvent. The solvent capable of being used is the same as in Embodiment 2. As a result of the drying process, the solvent in the varnish is at least partially removed and the fluororesin becomes semicured (the so-called “B-stage”). The impregnating step can be carried out by any method known in the art, such as dipping or application. By impregnating the fluororesin and optional initiator multiple times, the resin content in the prepreg can be adjusted. The conditions (temperature and time) of the drying step depend on the type of fluororesin and the type of optional reaction initiator and/or solvent. For example, the drying step can be carried out by heating to a temperature of to 170° C. for 1 to 10 minutes.

Embodiment 4 of the present invention relates to a prepreg, including a semicured product of the resin composition according to Embodiment 2 and a fibrous base material. The fibrous base material capable of being used in the present embodiment is the same as that of Embodiment 3.

The prepreg of the present embodiment can be formed by impregnating the resin composition of Embodiment 2 into the fibrous base material and drying the resin composition. Here, the resin composition to be impregnated is preferably in a varnish state containing a solvent. As a result of the drying process, the solvent in the varnish is at least partially removed and the resin composition becomes semicured (the so-called “B-stage”). The impregnating step can be carried out by any method known in the art, such as dipping or application. By impregnating the resin composition multiple times, the resin content in the prepreg can be adjusted. The conditions (temperature and time) of the drying step depend on the type of fluororesin, crosslinking agent, and optional solvent which are included in the resin composition. For example, the drying step can be carried out by heating to a temperature of 80° C. to 170° C. for 1 to 10 minutes.

Embodiment 5 of the present invention relates to a copper clad laminate, including a cured product of the prepreg according to Embodiment 3 or 4 and at least one copper layer.

The copper clad laminate of the present embodiment can be formed by laminating one or more prepregs, laminating a copper foil on one or both surfaces thereof, and heating and pressing the obtained laminated product to integrate them. The resin composition in the copper clad laminate is preferably in a state in which curing is complete (the so-called “C stage”). The conditions of the heating and pressing process can be appropriately set based on the thickness of the copper clad laminate to be manufactured, the composition of the resin composition in the prepreg, etc. For example, the copper clad laminate can be manufactured by heating to a temperature of 170° C. to 220° C. for 60 to 150 minutes and applying a pressure of 1.5 MPa (gauge pressure) to 5.0 MPa (gauge pressure).

Embodiment 6 of the present invention relates to a printed circuit board, including a cured product of the prepreg according to Embodiment 3 or 4 and a conductor pattern formed on the surface of the cured product.

The printed circuit board of the present embodiment can be manufactured by etching the copper layer of the copper clad laminate of Embodiment 5 to form a conductor pattern. Alternatively, the printed circuit board can be manufactured via a method in which one or more prepregs are laminated, heated, and pressed to form a laminated body, with the conductive material laminated in a pattern on the surface of the laminated body to form a conductor pattern.

### EXAMPLES

### Example 1: Synthesis of Fluororesin (1-1)

A glass reaction vessel was filled with 1.009 g (3.0 mmol) of 2,2-bis (4-hydroxyphenyl) hexafluoropropane (bisphenol AF) and 0.912 g (6.6 mmol) of potassium carbonate. The glass reaction vessel was decompressed to a vacuum and then substituted with nitrogen. 10 mL of DMAc was subsequently added to the glass reaction vessel. The reaction mixture was heated to 150° C. and stirred for 3 hours. Upon completion of heating, the reaction mixture was cooled to room temperature. 0.802 g (2.4 mmol) of decafluoro biphenyl was subsequently added to the reaction mixture. The reaction mixture was heated to 70° C. and stirred for 4 hours. The reaction mixture was subsequently shielded, after which 0.17 mL (0.233 g, 1.2 mmol) of 2,3,4,5,6-pentafluorostyrene was added thereto. Stirring was continued at a temperature of 70° C. for 15 hours. Upon completion of stirring, the reaction mixture was cooled to room temperature. The reaction mixture was subsequently poured into 0.5 L of pure water. The reaction mixture was suction filtered and the obtained solid was washed with pure water and methanol. The washed solid was decompressed and dried to obtain approximately 1.52 g of fluororesin (1-1).

### Example 2: Synthesis of Fluororesin (1-2)

The procedure of Example 1 was repeated except that 0.811 g (3.0 mmol) of 2,2-bis(4-hydroxyphenyl)-4-methylpentane was used instead of bisphenol AF to obtain approximately 1.21 g of fluororesin (1-2).

### Example 3: Synthesis of Fluororesin (1-3)

The procedure of Example 1 was repeated except that 0.805 g (3.0 mmol) of 1,1-bis(4-hydroxyphenyl) cyclohexane (bisphenol Z) was used instead of bisphenol AF to obtain approximately 1.14 g of fluororesin (1-3).

### Example 4 Synthesis of Fluororesin (1-5)

Approximately 1.12 g of fluororesin (1-5) was obtained by repeating the procedure of Example 1 except that 1.039 g of (3.0 millimole) 1,4-bis(2-(4-hydroxyphenyl)-2-propyl)benzene (bisphenol P) was used instead of bisphenol AF.

### Example 5 Synthesis of Fluororesin (1-6)

Approximately 1.22 g of fluororesin (1-6) was obtained by repeating the procedure of Example 3, except that 0.21 mL (0.359 g, 1.2 millimole) of 3-(pentafluorophenyl)pentafluoro-1-propene was used instead of 2,3,4,5,6-pentafluorostyrene.

### Comparative Example 1: Synthesis of Fluororesin (C-1)

Approximately 1.09 g of fluororesin (C-1) was obtained by repeating the procedure of Example 1, except that 0.14 mL (0.143 g, 1.2 millimole) of 4-fluorostyrene was used instead of 2,3,4,5,6-pentafluorostyrene.

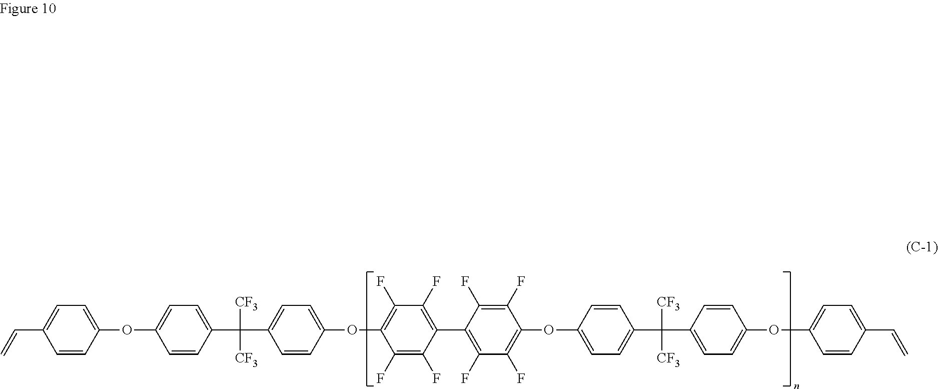

### Comparative Example 2: Synthesis of Fluororesin (C-2)

Approximately 1.11 g of fluororesin (C-2) was obtained by repeating the procedure of Example 1, except that 0.12 mL (0.125 g, 1.2 millimole) of methacryloyl chloride was used instead of 2,3,4,5,6-pentafluorostyrene.

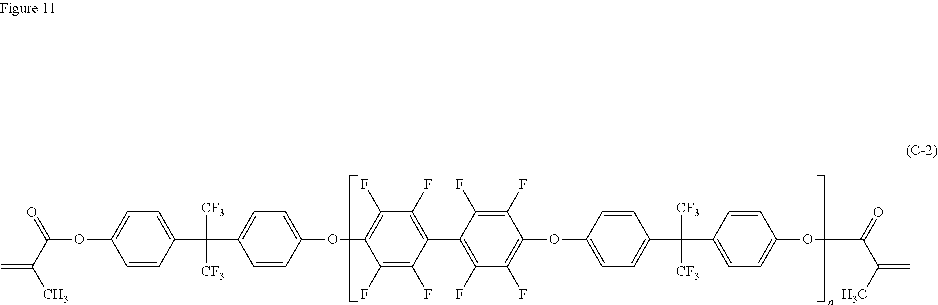

### Evaluation 1

Approximately 5 mg of the fluororesins obtained in Example 1 to 5 and Comparative Examples 1 to 2 were weighed out, after which the thermal weight (TG) curve was measured upon heating from 23° C. to 500° C. at a heating rate of 10° C./min using a thermogravimetric differential thermal analyzer (TG-DTA). The obtained TG curve was analyzed, after which the temperature at which the weight was reduced by 1% from prior to the measurement was regarded as the 1% decomposition temperature. The obtained results are indicated in Table 1.

### Evaluation 2

The fluororesins obtained in Examples 1 to 5 and Comparative Examples 1 and 2 were analyzed using a differential scanning calorimeter (manufactured by PerkinElmer Co., Ltd.). The temperature profile used was as follows:
(1) heating from 30° C. to 350° C. at a heating speed of 50° C./min.
(2) maintaining a temperature of 350° C. for 1 minute.
(3) cooling to 30° C. at a heating speed of 10° C./min.
(4) maintaining a temperature of 30° C. for 1 minute.
(5) heating to 350° C. at a heating speed of 10° C./min.

From the melting curve obtained in step (5), the Tmg according to ASTM D3418-15 (midpoint temperature, the temperature at the point at which a straight line (that was equidistant in the longitudinal axis direction from an extended straight line of each baseline) crossed the curve of the stepwise change portion of the glass transition) was determined and regarded as the glass transition temperature (Tg) of the fluororesin. The obtained results are indicated in Table 1.

### Evaluation 3

Toluene was added to the fluororesins obtained in Examples 1 to 5 and Comparative Examples 1 to 2, after which the mixture was heated to 80° C. to obtain a 50 mass % toluene solution of the fluororesin. Here, when the fluororesin was completely dissolved, it was determined that the fluororesin was toluene soluble.

### Evaluation 4

An equivalent amount of cyclohexanone was added to the fluororesin obtained in Examples 1-5, and the mixture was heated to 80° C. and stirred to obtain a 50% by mass solution of the fluororesin. The obtained cyclohexanone solution was applied onto a 0.1 mm aluminum sheet. The obtained coating material was heated using a hot plate for 30 minutes at 110° C. and for 1 hour at 160° C. to remove the solvent (cyclohexanone). The obtained sheet coated with the fluororesin was heated at 220° C. for 2 hours using a hot plate to melt the fluororesin. Thereafter, the sheet was cooled to room temperature overnight, and then the coating film was peeled to form a test piece.

Fluororesin obtained in comparison examples 1-2 was difficult to dissolve in cyclohexanone. Therefore, Dimethylacetamide (DMAc) was added at twice the amount of fluororesin, and the mixture was heated and stirred at 80° C. to obtain about 33 mass % solution of fluororesin. Thereafter, the test piece was obtained by the same procedure as above.

The dielectric constant and dielectric loss of the test piece at a frequency of 1 GHz was determined using an RF impedance/material analyzer (E4991A available from Agilent Technologies). The obtained results are indicated in Table 1.

### (Example 6) Manufacture of a Resin Composition Containing Fluorine Resin (I-1)

Toluene was added to 0.5 g of fluororesin (1-1), after which the mixture was heated to 80° C. to obtain a 50 mass % toluene solution of the fluororesin (I-1). 0.05 g (10 mass % based on the fluororesin) of benzoyl peroxide and 0.2 g of triallyl isocyanurate (TAIC) were added to the obtained toluene solution at a temperature of 80° C. and stirred for 10 minutes to obtain a resin composition. The mass ratio of the fluororesin (1-1) to the TAIC was 7:3.

### Evaluation 5

The resin composition obtained in an example 6 is applied on a 0.1 mm thick aluminum sheet. The obtained coating material was heated at 110° C. for 60 minutes using a hot plate to remove the toluene. A cured product of the resin composition was obtained by heating the sheet, which was coated with the resin composition, at 220° C. for 2 hours using a hot plate. Thereafter, the sheet was cooled to room temperature overnight, and then the coating film was peeled to form a test piece.

The dielectric constant and dielectric loss of the test piece at a frequency of 1 GHz was determined using an RF impedance/material analyzer (E4991A available from Agilent Technologies). The obtained results are indicated in Table 1.

TABLE 1
Table 1: Evaluation of resins and resin compositions

| | | Cross- | | 1% decomposition | | Dielectric | Dielectric |
|---|---|---|---|---|---|---|---|
| | | linking | Toluene | temperature | Tg | constant | Loss |
| Example | Resin | agent | solubility | (° C.) | (° C.) | (1 GHz) | (1 GHz) |
| Example 1 | (I-1) | — | ∘ | 201 | 143 | 2.38 | ≤0.001 |
| Example 6 | (I-1) | TAIC | — | — | — | 2.65 | 0.0016 |
| Example 2 | (I-2) | — | ∘ | 236 | 115 | 2.81 | ≤0.001 |
| Example 3 | (I-3) | — | ∘ | 344 | 135 | 2.65 | ≤0.001 |
| Example 4 | (I-5) | — | ∘ | 337 | 136 | 2.35 | ≤0.001 |
| Example 5 | (I-6) | — | ∘ | 237 | 122 | 2.43 | ≤0.001 |
| Comparative | (C-1) | — | x | 268 | 195 | 2.67 | 0.016 |
| Example 1 | | | | | | | |
| Comparative | (C-2) | — | x | 114 | 112 | 2.67 | 0.0048 |
| Example 2 | | | | | | | |

1. A fluorine resin having the structure of Formula (I): 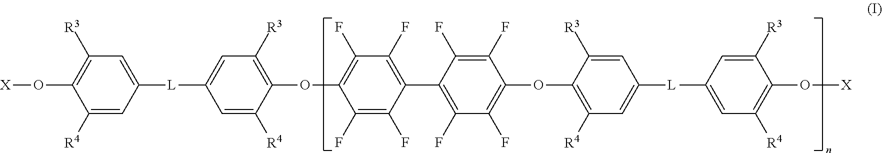
wherein: L has the structure of formula (II) or formula (III), 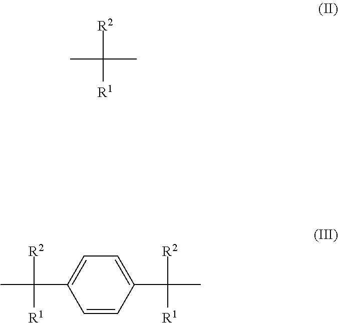
R¹ and R² are each independently a group selected from a group consisting of a hydrogen atom, C₁-C₁₀ alkyl groups, C₁-C₁₀ haloalkyl groups, and C₆-C₁₀ aryl groups, or R¹ and R² may be combined to form a ring structure that may include a substituent,
R³ and R⁴ are each independently a group selected from a group consisting of hydrogen atoms, fluorine atoms, C₁-C₁₀ saturated or unsaturated hydrocarbon groups in which some or all of the hydrogen atoms may be substituted by a halogen, and C₆-C₁₀ aryl groups in which some or all of the hydrogen atoms may be substituted by a halogen,
n is in the range of 1 to 100, and
X is a group containing an olefinic carbon-carbon double bond or a carbon-carbon triple bond and at least one fluorine atom.

2. A resin composition, comprising the fluororesin according to claim 1 and a crosslinking agent.

3. A prepreg, comprising a semicured product of the fluororesin according to claim 1 and a fibrous base material.

4. A prepreg, comprising a semicured product of the resin composition according to claim 2 and a fibrous base material.

5. A copper clad laminate, comprising a cured product of the prepreg according to claim 3 and at least one copper layer.

6. A printed circuit board, comprising a cured product of the prepreg according to claim 3 and a conductor pattern formed on the surface thereof.
